(19) United States
(12) Patent Application Publication
(10) Pub. No.: US 2008/0042222 A1
(43) Pub. Date: Feb. 21, 2008

(54) TRENCH MOSFET WITH COPPER METAL CONNECTIONS

(75) Inventor: Fwu-Iuan Hshieh, Saratoga, CA (US)

Correspondence Address: HAMRE, SCHUMANN, MUELLER & LARSON, P.C., P.O. BOX 2902, MINNEAPOLIS, MN, 55402-0902, US

(73) Assignee: FORCE MOS TECHNOLOGY CO., LTD., SMB (KY)

(21) Appl. No.: 11/736,150

(22) Filed: Apr. 17, 2007

Related U.S. Application Data
(60) Provisional application No. 60/838,113, filed on Aug. 16, 2006.

(51) Int. Cl. H01L 29/78; H01L 21/336

(52) U.S. Cl. 257/411; 438/287; 438/296; 257/E29.255; 257/E21.409

(57) ABSTRACT

A trench Metal-Oxide-Semiconductor Field Effect Transistor (MOSFET) with copper metal connections. A substrate is provided with a plurality of trenches. A gate oxide layer is formed on the substrate and the sidewalls and bottom of the trenches. A conductive layer is filled in the trenches to be used as a gate of the MOSFET. A plurality of body and source regions is formed in the epi layer. An insulating layer is formed on the substrate and forms with a plurality of metal contact holes therein for contacting respective source and body regions. A barrier metal layer is formed on the insulating layer and the sidewalls and bottoms of the metal contact holes in direct contact with respective source and body regions. A copper metal layer is formed on the metal layer connected to respective source and body regions to form metal connections of the MOSFET.

### CROSS REFERENCE

The present application claims the priority of provisional application serial number, 60/838,113 which was filed on Aug. 16, 2006.

### FIELD OF THE INVENTION

The present invention relates to a structure of a trench MOSFET and the method for manufacturing the same, and more particularly, to a structure of a trench MOSFET with copper metal connections and the method for manufacturing the same.

### BACKGROUND OF THE INVENTION

In the structure of a trench Metal-Oxide-Semiconductor Field Effect Transistor (MOSFET) or vertical transistor, the gate of the transistor is formed in a trench on top of a substrate and the source/drain regions are formed on both sides of the gate. This type of vertical transistor allows high current to pass through and channel to be turned on/off at a low voltage.

Referring to FIG. 1, a cross-sectional diagram of the structure of a trench MOSFET is shown. An N-type doping epitaxial region 105 is provided on a N+ substrate 100. A plurality of trenches is formed in the region 105 that having lower doping concentration than the substrate 100. An oxide layer 115 and gates 130 are covered in the trenches. P-type doping regions (hereinafter call P-body) 110 are formed on both sides of the gates 130. N+ doping regions 125 are formed in the P-body 110. N+ doping regions 125 are used as the source regions of the transistor. Metal connections for the gates 130, P-body 110 and N+ doping regions 125 are formed from tungsten metal layers 145 and barrier layers 140 in an insulating layer 135. Aluminum metal layer 150 above the tungsten metal layer 145 is used as a second layer of metal connection. However, using tungsten metal plug as the metal connections in the trench MOSFET may cause poor thermal conduction as the size of the transistor shrinks.

Prior arts (U.S. Pat. Nos. 6,462,376 and 6,888,196) have 2-dimensional source contact with tungsten plug which is connected with aluminum alloys as front metal. The metal system has thermal conduction issue when die size shrinks as a result of increasing cell density.

The present invention provides a new structure of trench MOSFET, which uses copper as front metal structure and has a better contact and thermal conduction than prior art.

### SUMMARY

This invention provides a trench Metal-Oxide-Semiconductor Field Effect Transistor (MOSFET) with copper metal connections. A substrate is provided with a plurality of trenches. A gate oxide layer is formed on the sidewalls and bottom of the trenches. A conductive layer is filled in the trenches to be used as a gate of the MOSFET. A plurality of source and body regions is formed in the epi. An insulating layer is formed on the epi and forms with a plurality of metal contact holes therein for contacting respective source and body (means P-body) regions. A barrier metal layer is formed on the insulating layer and the sidewalls and bottoms of the metal contact holes in direct contact with respective source and body regions. A copper metal layer is formed on the metal layer connected to respective source and drain regions to form metal connections of the MOSFET.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional diagram depicting a trench MOSFET using tungsten metal and aluminum metal as metal connections for the source/drain regions of the MOSFET;

FIGS. 2 to 8 are cross-sectional diagrams illustrating forming a trench MOSFET on a substrate in accordance with the first embodiment of the present invention, wherein copper metal layer is used as metal connections for the source/drain regions of the MOSFET; and

FIG. 9 is a cross-sectional diagram illustrating forming a trench MOSFET on a substrate in accordance with the second embodiment of the present invention, wherein copper metal layer is used as metal connections for the source/body regions of the MOSFET and a gate oxide layer forming a gate structure has a large thickness.

### DETAILED DESCRIPTION OF THE EMBODIMENTS

The present invention is described by the following specific embodiments. Those with ordinary skills in the arts can readily understand the other advantages and functions of the present invention after reading the disclosure of this specification. The present invention can also be implemented with different embodiments. Various details described in this specification can be modified based on different viewpoints and applications without departing from the scope of the present invention.

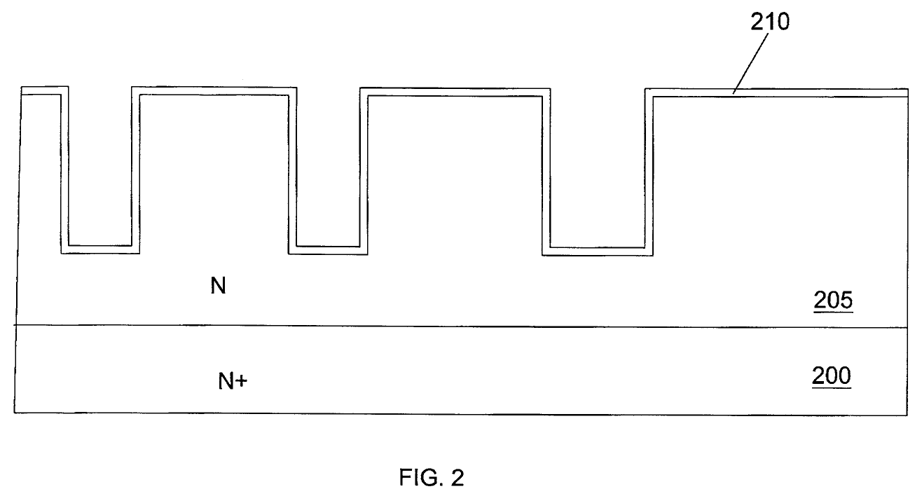

Referring to FIG. 2, an N+ doped substrate 200 having a N-type doping epi layer region 205 thereon is provided. Lithography and dry etching processes are performed to form a plurality of trenches in the N-type epi layer 205. Then, a deposition or thermally grown process is performed to form a silicon oxide layer on the surface of the N-type doping region 205 and the trenches, which acts as a gate oxide layer 210 of a trench MOSFET. Prior to the gate oxide layer 210 is formed, a sacrificial oxide is grown and wet etched for removal silicon damage along the trench surface induced by the dry trench etch.

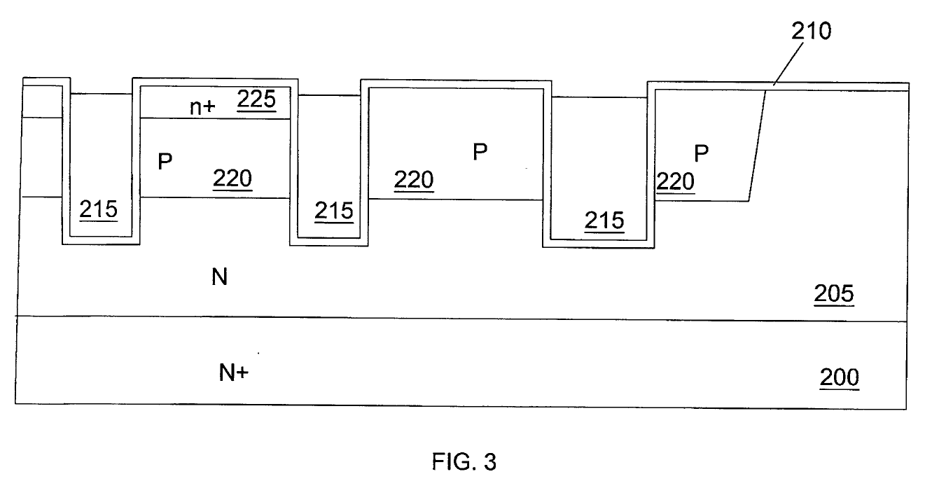

Referring to FIG. 3, a doped polysilicon layer is formed on the gate oxide layer 210 and filled in the trenches by a deposition process. Thereafter, doped polysilicon layer on the gate oxide layer 210 is removed by a dry etching process or a CMP (chemical-mechanical polishing process), forming a gate structure 215 of the trench MOSFET in the trench. Then, a mask (not shown in FIG. 3) is formed over the gate oxide layer 210 and the gate structure 215 by lithography. Then, P-body regions 220 are formed in the N-type doping region 205 by an ion implantation and diffusion processes. After that, another mask is formed so as to facilitate formation of N+ doping regions 225 in the P-body regions 220 by ion implantation and thermal diffusion processes. The N+ doping regions 225 are the source regions of the trench MOSFET (hereinafter call source).

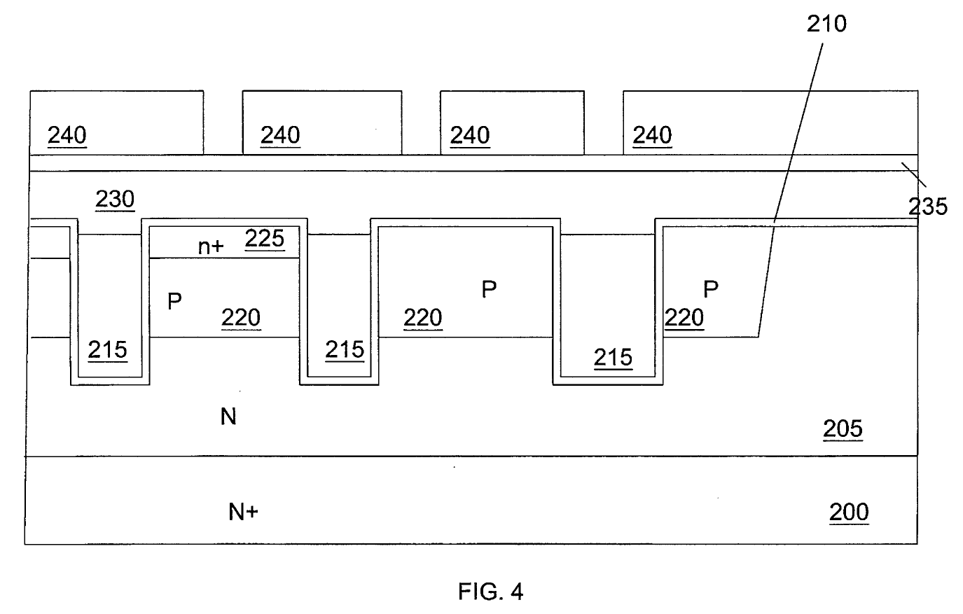

Referring to FIG. 4, an insulating layer 230 is formed on the gate oxide layer 210 and the gate structure 215. This insulating layer 230 is a silicon dioxide layer formed by a deposition process. A barrier layer 235 is further formed on the insulating layer 230 by a deposition process. The barrier layer 235 is made of silicon nitride or silicon oxynitride material. After the deposition of the barrier layer 235, a mask 240 is formed on the surface of the barrier layer 235 by lithography. This mask 240 defines the locations of metal contacts of the trench MOSFET. More particularly, the areas to be formed as metal contacts are exposed from the mask 240.

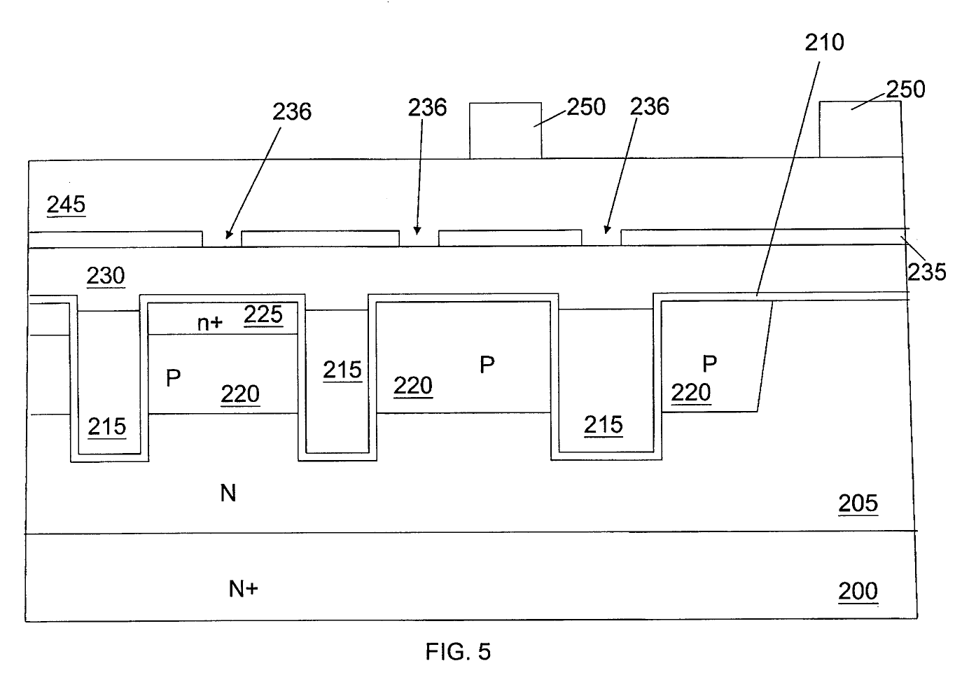

Referring to FIG. 5, the locations of the metal contacts 236 are defined on the barrier layer by etching. After the etching process, the pattern of the barrier layer defines the locations of the metal contacts. Then, another silicon dioxide layer 245 is deposited, and a metal mask 250 is defined on the silicon dioxide layer 245.

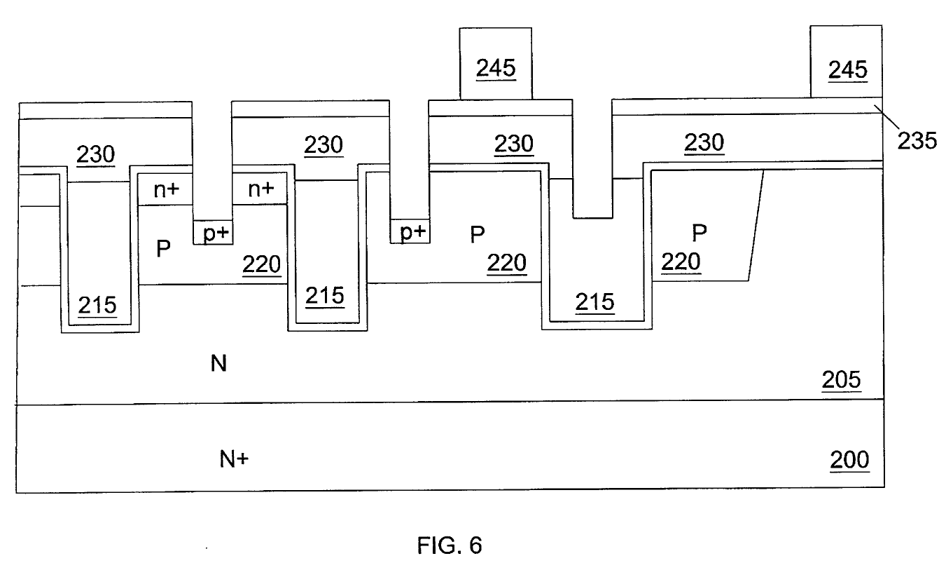

Referring to FIG. 6, a dry etching process is performed by using the metal mask 250 and the barrier layer 235 as the etching mask, such that metal contact holes are formed in the barrier layer 235, the insulating layer 230, the N+ source 225, the P-body regions 220, and the gate structure 215. Then, an ion implantation process is carried out to form P+ heavily-doped regions 220 at the bottom of the metal contact holes.

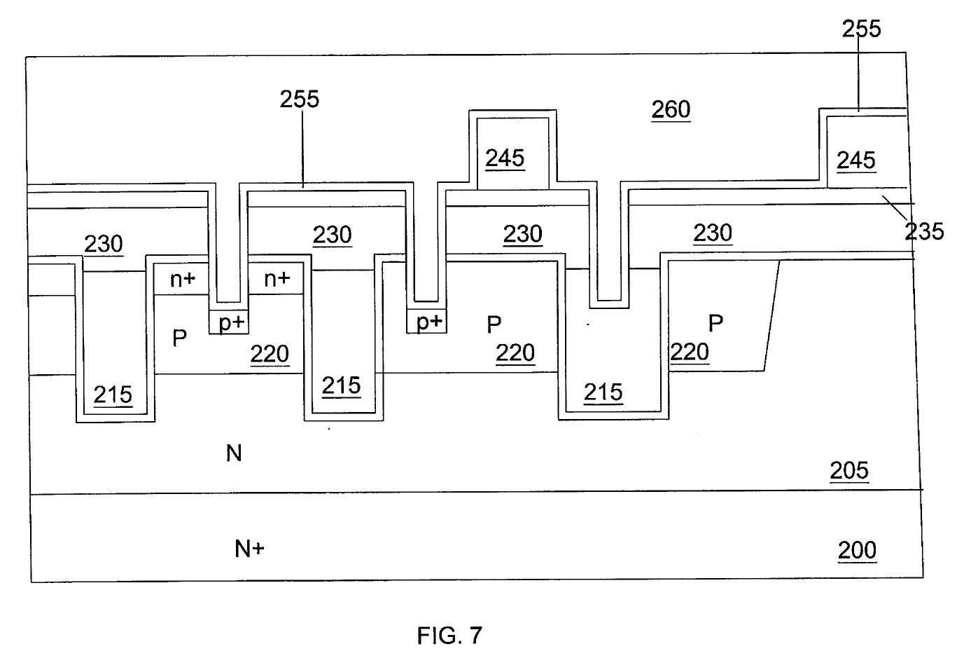

Referring to FIG. 7, a barrier metal layer 255 is deposited in the metal contact holes and on the metal mask 250 and barrier layer 235. Thereafter, a copper metal layer 260 is deposited by electroplating on the barrier metal layer 255 after copper seed layer deposition to fill back the metal contact holes, forming metal plugs, i.e. metal connections for the trench MOSFET. According to an embodiment of the present invention, the barrier metal layer 255 is formed by depositing Ta metal then TaN material, or depositing Ta metal then TiN material.

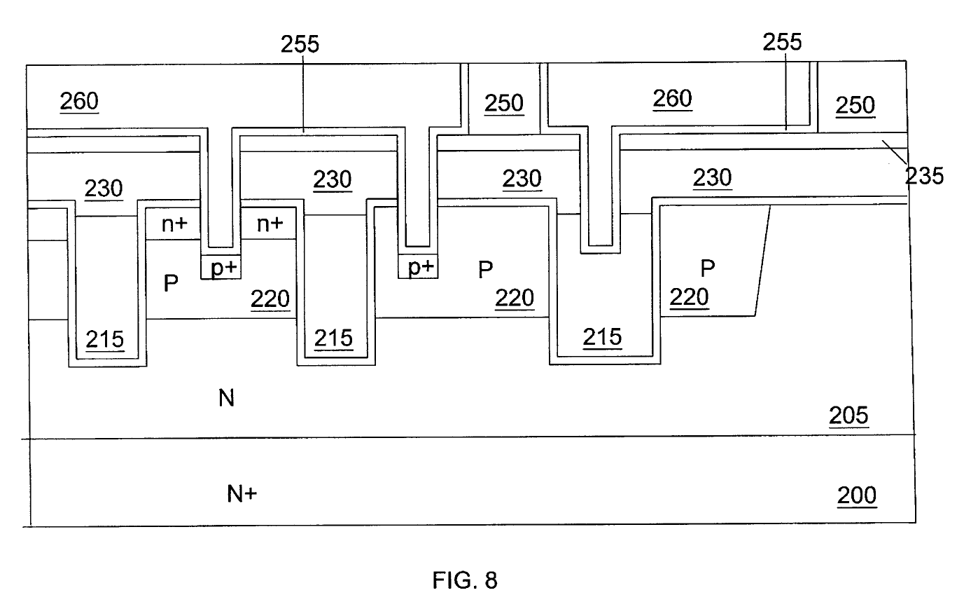

Referring to FIG. 8, the excess copper metal layer 260 and barrier metal layer 255 are removed by CMP process to complete the formation of metal connections of the trench MOSFET.

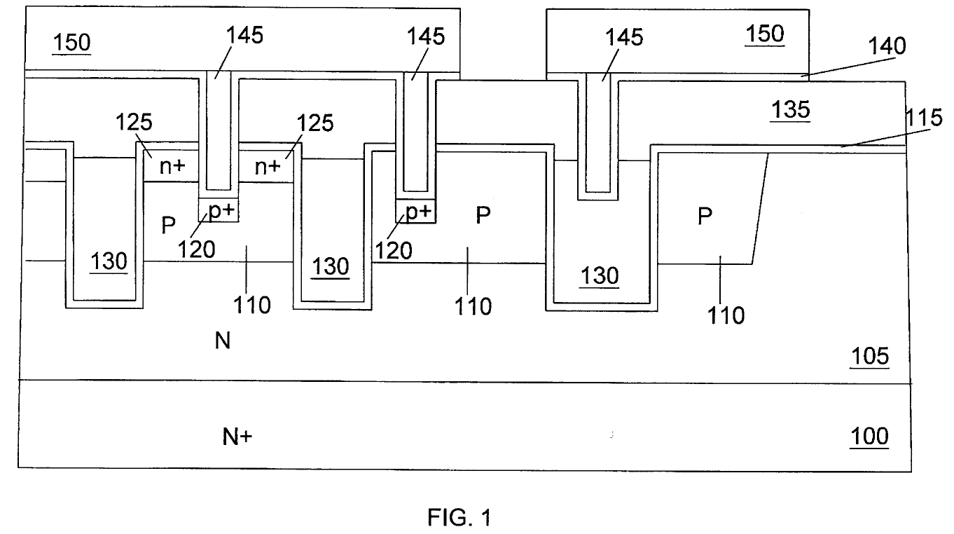

According to the manufacturing processes of a trench MOSFET shown in FIGS. 1 to 8, the barrier layer and metal mask 250 are used to define the locations and pattern of the metal contact holes and metal connections, and then copper metal are filled back into the metal contact holes to form the metal connections. Instead of forming metal plugs and metal connections using tungsten metal and aluminum metal as in the prior arts, copper metal is used as the front metal layer of the trench MOSFET. The thermal conduction issue for the trench MOSFET is eliminated as transistor size is reduced, since copper metal has better thermal conductivity.

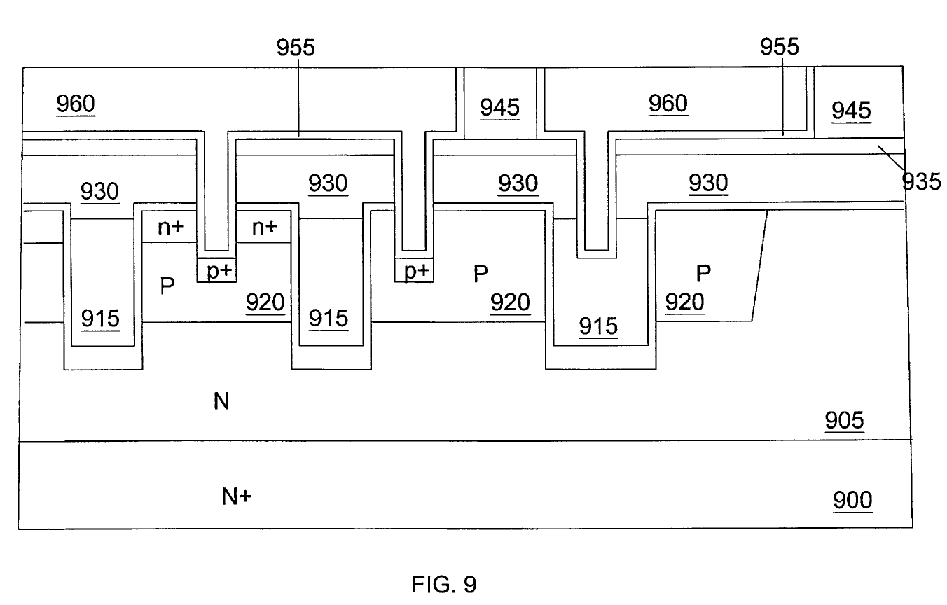

Referring to FIG. 9, a cross-sectional diagram depicting a trench MOSFET according to a second embodiment of the present invention is shown. An N-type doping layer 905 is covered on the N+ doped substrate 900. A plurality of trenches are formed in the N-type doping layer 905. A gate oxide layer 910 is covered in the trenches with thicker oxide on trench bottom than trench sidewall. A doped polysilicon material is filled back into the trenches to form gate structures 915. A P-body 920 is then formed in the N-type doping layer 905. An N+ source 925 is further formed in the P-body layer 920 to function as the source regions of the MOSFET. The metal contact holes are defined by an insulating layer 930, a barrier layer 935 and an oxide layer 945 on the gate oxide layer 910 and the gate structures 915. Then, a barrier metal layer 955 and a copper metal layer 960 are sequentially filled back into the metal contact holes covering the insulating layer 930 and the barrier layer 935, thereby forming the metal contacts and metal connections for the trench MOSFET. The second embodiment shown in FIG. 9 is different from the first embodiment shown in FIG. 8 in that the thickness of the gate oxide layer 910 on trench bottom is greater than that of trench sidewall. When the thickness of the gate oxide layer on trench bottom is greater but same on trench sidewall, its capacitance between gate and drain is smaller, thus the speed of the trench MOSFET is faster without affecting on-resistance.

Although various embodiments are specifically illustrated and described herein, it will be appreciated that modifications and variations of the present invention are covered by the above teachings and are within the purview of the appended claims without departing from the spirit and intended scope of the invention.

What is claimed is:

1. A trench Metal-Oxide-Semiconductor Field Effect Transistor (MOSFET) with copper as source metal connections, comprising:
a plurality of trenches formed on top of epi layer;
a gate oxide layer formed on the sidewalls and bottom of the trenches;
a conductive layer filled in the trenches to be used as a gate of the MOSFET;
a plurality of source and body regions formed in the epi layer;
an insulating layer deposited on the epi layer formed with a plurality of metal contact holes therein for contacting respective source and body regions;
a barrier metal layer on the insulating layer and the sidewalls and bottoms of the metal contact holes in direct contact with respective source and body regions; and
a copper metal layer on the metal layer connected to respective source and body regions forming metal connections of the MOSFET.

2. The transistor of claim 1, wherein the transistor is formed in an N-type doping epi region on the heavily doped N-type substrate.

3. The transistor of claim 1, wherein the transistor is formed in an P-type doping epi region on the heavily doped P-type substrate.

4. The transistor of claim 1, wherein the insulating layer is made of silicon dioxide layer and silicon nitride layer, the silicon nitride layer defining locations and pattern of the metal contact holes and metal connections.

5. The transistor of claim 1, wherein the barrier metal layer is formed by depositing Ta metal then TaN material.

6. The transistor of claim 1, wherein the barrier metal layer is formed by depositing Ta metal then TiN material.

7. The transistor of claim 1, wherein heavily-doped regions are disposed at the bottoms of the metal contact holes.

8. The transistor of claim 1, wherein the gate oxide layer in trench gates is single oxide of which oxide thickness nearly uniform along trench sidewall and bottom.

9. The transistor of claim 1, wherein the gate oxide layer at the bottoms of trench gates has a significant larger thickness than trench sidewall so as to reduce the capacitance of the gate oxide layer.

10. A method for manufacturing a trench MOSFET with copper metal connections, comprising the following steps:
providing a epi layer on heavily doped substrate;
forming a plurality of trenches in the epi layer;
covering a gate oxide layer on the sidewalls and bottom of the trenches;
forming a conductive layer in the trenches to be used as the gate of MOSFET;
forming a plurality of body and source regions in the epi layer;
forming an insulating layer on the epi layer;
forming a plurality of contact openings in the insulating layer connected to respective source regions;
forming a metal layer on the insulating layer and the sidewalls and bottoms of the contact openings in direct contact with respective source and body regions; and
a copper metal layer on the metal layer connected to respective source and body regions forming metal connections of the MOSFET.

11. The method of claim 10, wherein the transistor is formed in an N-type doping epi region on the heavily doping N+ substrate for N channel trenasitors and P-type doping epi region on the heavily doping P+ substrate for P channel trenasitors and.

12. The method of claim 10, wherein the insulating layer is made of silicon dioxide layer and silicon nitride layer, the silicon nitride layer defining locations and pattern of the metal contact holes and metal connections.

13. The method of claim 10, wherein the barrier metal layer is formed by depositing Ta metal then TaN material.

14. The method of claim 10, wherein the barrier metal layer is formed by depositing Ta metal then TiN material.

15. The method of claim 10, wherein heavily-doped regions are disposed at the bottoms of the metal contact holes.

16. The method of claim 10, wherein the gate oxide layer at the bottoms of the metal contact holes has a large thickness so as to reduce the capacitance of the gate oxide layer.
